(19) United States
(12) Patent Application Publication
(10) Pub. No.: US 2026/0101614 A1
(43) Pub. Date: Apr. 9, 2026

(54) COEFFICIENT OF THERMAL EXPANSION STRUCTURES IN SUBMOUNTS OF LIGHT-EMITTING DIODES

(71) Applicant: CreeLED, Inc., Durham, NC (US)

(72) Inventors: Michael Check, Holly Springs, NC (US); Colin Blakely, Raleigh, NC (US)

(21) Appl. No.: 18/987,626

(22) Filed: Dec. 19, 2024

Related U.S. Application Data
(60) Provisional application No. 63/704,348, filed on Oct. 7, 2024.

(51) Int. Cl. H10H 20/85; H10H 20/857; H10H 20/858

(52) U.S. Cl. CPC H10H 20/8508; H10H 20/8502; H10H 20/8504; H10H 20/857; H10H 20/8583; H10H 20/8585

(57) ABSTRACT

Light-emitting diode (LED) devices and more particularly coefficient of thermal expansion (CTE) structures in submounts of LEDs are disclosed. Thermal expansion structures include arrangements of vias within submounts that provide variable CTE values across submount surfaces and/or within thicknesses of submounts. Vias may comprise air-filled vias and/or vias filled with various materials that provide variable CTE values. Vias may further be formed with variable thicknesses within submounts to further tailor CTE values. Submounts may include flexible submounts adept for mounting to irregular surfaces with vias structure to provide CTE compensation. Further aspects are described in the context of chip-scale packaging.

### RELATED APPLICATIONS

This application claims the benefit of provisional patent application Ser. No. 63/704,348, filed Oct. 7, 2024, the disclosure of which is hereby incorporated herein by reference in its entirety.

### FIELD OF THE DISCLOSURE

The present disclosure relates to light-emitting diode (LED) devices, and more particularly to coefficient of thermal expansion structures in submounts of LEDs.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to coefficient of thermal expansion (CTE) structures in submounts of LEDs. Thermal expansion structures include arrangements of vias within submounts that provide variable CTE values across submount surfaces and/or within thicknesses of submounts. Vias may comprise air-filled vias and/or vias filled with various materials that provide variable CTE values. Vias may further be formed with variable thicknesses within submounts to further tailor CTE values. Submounts may include flexible submounts adept for mounting to irregular surfaces with vias structure to provide CTE compensation. Further aspects are described in the context of chip-scale packaging.

In certain aspects, an LED package comprises: a submount; a first bonding pad on the submount; an LED chip mounted to the first bonding pad; and a first via and a second via extending through the submount and at least a portion of the first bonding pad, the first via having a first coefficient of thermal expansion that is different than a second coefficient of thermal expansion of the second via. The LED package may further comprise a second bonding pad on the submount, wherein an anode pad of the LED chip is bonded to the first bonding pad and a cathode of the LED chip is bonded to the second bonding pad. The LED package may further comprise a third via and a fourth via extending through the submount and at least a portion of the second bonding pad, the third via having a third coefficient of thermal expansion that is different than a fourth coefficient of thermal expansion of the fourth via. The LED package may further comprise a first package mounting pad on a side of the submount opposite the first bonding pad, wherein the first via and the second via extend through at least a portion of the first package mounting pad. In certain embodiments, the submount comprises a flexible submount. In certain embodiments, the flexible submount comprises polyimide or polyethylene terephthalate. In certain embodiments, the first via comprises a different material than the second via. In certain embodiments, the first via comprises an air-filled via and the second via is filled with another material that is different from the air-filled via. In certain embodiments, the second via is entirely filled with the material that is different from the air-filled via. In certain embodiments, the first via and the second via comprise particles filled within a binder, and a loading concentration of the particles in the binder of the first via is different than the second via. In certain embodiments, the first via comprises a larger diameter than the second via. In certain embodiments, the second via is positioned proximate a center region of the first bonding pad, and the first via is positioned proximate an end of the first bonding pad. In certain embodiments, the first via is positioned proximate a center region of the first bonding pad, and the second via is positioned proximate an end of the first bonding pad. In certain embodiments, a diameter of the first via progressively increases or decreases through the submount. In certain embodiments, a diameter of the second via is consistent through a thickness of the submount. In certain embodiments, a first portion of the first via is filled with a different material than a second portion of the first via.

In another aspect, an LED package comprises: a submount; a first bonding pad and a second bonding pad on a first side of the submount; an LED chip bonded to the first bonding pad and the second bonding pad; and a first mounting pad and a second mounting pad on a second side of the submount opposite the first side, the first mounting pad and the second mounting pad comprising tapered thicknesses on the second side of the submount. In certain embodiments, the tapered thicknesses of the first mounting pad and the second mounting pad decrease in directions toward a center of the second side of the submount. In certain embodiments, the submount is configured to flex so that the first mounting pad and the second mounting pad form planar mounting surfaces on the second side of the submount. The LED package may further comprise at least one via extending through the submount and at least a portion of the first bonding pad.

In another aspect, an LED package comprises: a submount; a first bonding pad, a second bonding pad, and a third bonding pad on a first side of the submount; and an LED chip bonded to the first bonding pad, the second bonding pad, and the third bonding pad, the LED chip being electrically connected to the first bonding pad and the second bonding pad, and the LED chip being electrically isolated from the third bonding pad. The LED package may further comprise a first via extending through the submount and at least a portion of the first bonding pad, a second via extending through the submount and at least a portion of the second bonding pad, and a third via extending through the submount and at least a portion of the third bonding pad. In certain embodiments, the third via comprises a larger diameter than the first via.

In another aspect, an LED chip comprises: a chip submount; a first bonding pad on the chip submount; an active LED structure bonded to the first bonding pad; and a first via and a second via extending through the chip submount and at least a portion of the first bonding pad, the first via having a first coefficient of thermal expansion that is different than a second coefficient of thermal expansion of the second via. The LED chip may further comprise a second bonding pad on the chip submount, wherein an anode pad of the active LED structure is bonded to the first bonding pad and a cathode of the active LED structure is bonded to the second bonding pad. The LED chip may further comprise a third via and a fourth via extending through the submount and at least a portion of the second bonding pad, the third via having a third coefficient of thermal expansion that is different than a fourth coefficient of thermal expansion of the fourth via. The LED chip may further comprise a first chip mounting pad on a side of the submount opposite the first bonding pad, wherein the first via and the second via extend through at least a portion of the first chip mounting pad. In certain embodiments, the chip submount comprises a flexible submount.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top perspective view of a submount structure for a light-emitting diode (LED) package according to principles of the present disclosure.

FIG. 1B is a top view of the submount structure of FIG. 1A.

FIG. 2 is a bottom view of an LED chip that may be mounted to the submount structure of FIGS. 1A and 1B.

FIG. 3A is a cross-sectional view of an exemplary LED package that includes the LED chip of FIG. 2 flip-chip mounted to the submount structure of FIGS. 1A and 1B.

FIG. 3B is another cross-sectional view of the LED package of FIG. 3A illustrating vias that extend through the same bonding pad.

FIG. 4 is a top view of a submount structure that is similar to the submount structure of FIGS. 1A and 1B with a different arrangement of vias.

FIG. 5 is a top view of a submount structure that is similar to the submount structure of FIG. 4 for another arrangement of vias.

FIG. 6 is a top view of a submount structure that is similar to the submount structure of FIG. 4 for another arrangement of vias.

FIG. 7 is a cross-sectional view of a submount structure similar to the submount structure of FIG. 6 for embodiments where the vias are air-filled vias.

FIG. 8 is a cross-sectional view of a submount structure similar to the submount structure of FIG. 7 for embodiments where the vias include air-filled vias and vias filled with other materials.

FIG. 9 is a cross-sectional view of a submount structure similar to the submount structure of FIG. 8 for embodiments where one or more of the vias are only partially filled.

FIG. 10 is a cross-sectional view of a submount structure similar to the submount structure of FIG. 7 for embodiments where diameters of one or more of the vias are variable through a thickness of the submount.

FIG. 11 is a cross-sectional view of a submount structure similar to the submount structure of FIG. 10 for embodiments where diameters of one or more of the vias are variable in opposing directions.

FIG. 12A is a cross-sectional view of an LED package similar to the LED package of FIGS. 3A and 3B for embodiments where the package mounting pads are formed with tapered thicknesses.

FIG. 12B is a cross-sectional view of the LED package of FIG. 12A after bonding of the LED chip to the submount.

FIG. 13 is a cross-sectional view of an LED package that is similar to the LED package of FIGS. 3A and 3B for embodiments where one or more of the vias have portions filled with different materials.

FIG. 14 is a cross-sectional view of an LED package that is similar to the LED package of FIG. 13 for a different arrangement of the vias.

FIG. 15 is a cross-sectional view of an LED package that is similar to the LED package of FIG. 13 for embodiments where one via is formed with a variable thickness while another via is formed with variable filler materials.

FIG. 16 is a cross-sectional view of an LED package that is similar to the LED package of FIGS. 3A and 3B for embodiments that include thermal dissipation structures.

FIG. 17A is a cross-sectional view of an LED wafer structure at a fabrication step before an LED wafer is bonded to a submount structure wafer according to principles of the present disclosure.

FIG. 17B is a cross-sectional view of the LED wafer structure at a fabrication step after the LED wafer is bonded to the submount structure wafer by way of a bonding material.

FIG. 17C is a cross-sectional view of the LED wafer structure at a fabrication step after the LED wafer structure is subdivided into individual LED chips.

FIG. 18 is a cross-sectional view of an LED package that includes one of the LED chips of FIG. 17C.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to coefficient of thermal expansion (CTE) structures in submounts of LEDs. Thermal expansion structures include arrangements of vias within submounts that provide variable CTE values across submount surfaces and/or within thicknesses of submounts. Vias may comprise air-filled vias and/or vias filled with various materials that provide variable CTE values. Vias may further be formed with variable thicknesses within submounts to further tailor CTE values. Submounts may include flexible submounts adept for mounting to irregular surfaces with vias structure to provide CTE compensation. Further aspects are described in the context of chip-scale packaging.

Before delving into specific details for aspects of the present disclosure, an overview of various elements that may be included in exemplary LED packages is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a submount.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Aspects of the present disclosure are also well suited for embodiments with flexible substrates. By way of example, a flexible submount may comprise a polyimide, a polyethylene terephthalate (PET), and the like with electrically conductive traces. Flexible submounts allow improved bonding in a conformal manner to other surfaces that may not be entirely planar.

Encapsulant materials, such as silicone, epoxy, or polymethyl methacrylate (PMMA), among others, may be formed to encapsulate the LED chips over a submount. In certain embodiments, one or more lumiphoric materials, such as phosphor particles, may be integrated or otherwise embedded within the encapsulant material. Moreover, encapsulant materials may be shaped to form single lens structures and/or multiple lens structures in a single LED package.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO2), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Aspects of the present disclosure relate to balancing coefficient of thermal expansion (CTE) between LED chips and corresponding submounts. The CTE of a submount material may be intentionally tailored by combining it with other materials to form a composite structure. By strategically selecting and arranging through vias with filler materials that provide disparate CTE values, the overall CTE of the composite structure may be adjusted to match specific design requirements. This approach involves cutting and filling a base material with carefully chosen fillers, which have been pre-characterized for their CTE properties. By tailoring the filler distribution and volume fraction, it is possible to achieve a desired CTE value that falls within a predetermined range, thus enabling the creation of materials with tailored thermal expansion characteristics. This composite modification technique has significant potential in various applications, where precise control over CTE is crucial for ensuring reliable performance under varying thermal conditions, such as bonding LED chip structures to submount structures.

Exemplary filler materials include metal particles or ceramic powders suspended in a binder. The loading of metal particles and/or ceramic powders may be increased or decreased to achieve a desired CTE value. By way of example, the filler materials may include TiO₂ particles in a binder of silicone or metal particles suspended in a binder of silicone. In other embodiments, the filler materials may include a continuous metal filler, such as solder, examples of which include tin-silver-copper (SAC), bismuth-tin, bismuth-indium, and the like. In another example, the filler may comprise air to provide a targeted CTE value. In still other examples, the filler may comprise graphene or a graphene composite that in addition to CTE tuning may further provide increased thermal dissipation for heat generated by the LED chip.

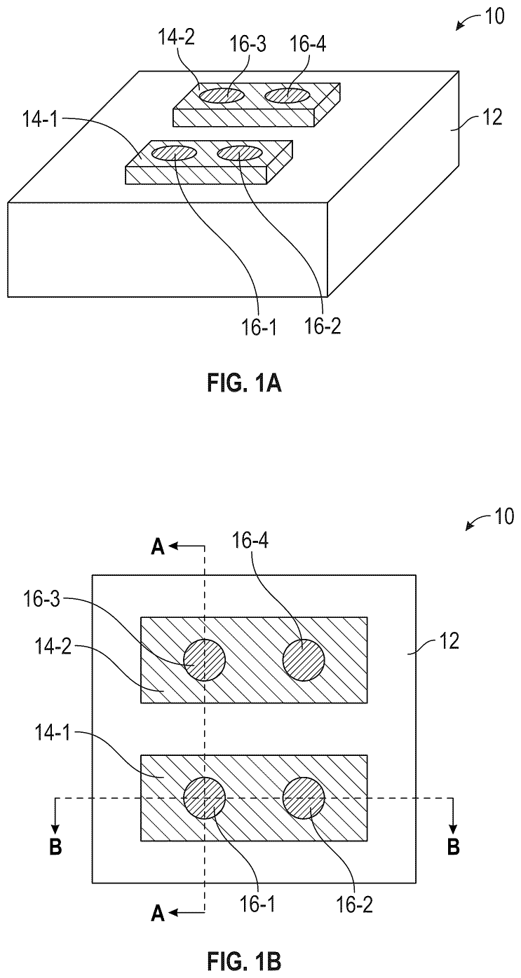

FIG. 1A is a top perspective view of a submount structure 10 for an LED package according to principles of the present disclosure. FIG. 1B is a top view of the submount structure 10 of FIG. 1A. The submount structure 10 is collectively formed by a submount 12 and bonding pads 14-1, 14-2 on a top surface thereof. As will be described later in greater detail, the bonding pads 14-1, 14-2 form a die attach area for receiving anode and cathode contacts of an LED chip. A number of vias 16-1 to 16-4 are provided that may extend through the bonding pads 14-1, 14-2 and the submount 12 of the submount structure 10. As described above, the material of the vias 16-1 to 16-4 is selected such to modify or tailor CTE values across the bonding pads 14-1, 14-2. In certain embodiments, the vias 16-1, 16-2 extending through the same bonding pad 14-1 may have different CTE values to balance bonding stress along the bonding pad 14-1. In a similar manner, the vias 16-3, 16-4 extending through the bonding pad 14-2 may have different CTE values from one another to balance bonding stress along the bonding pad 14-2.

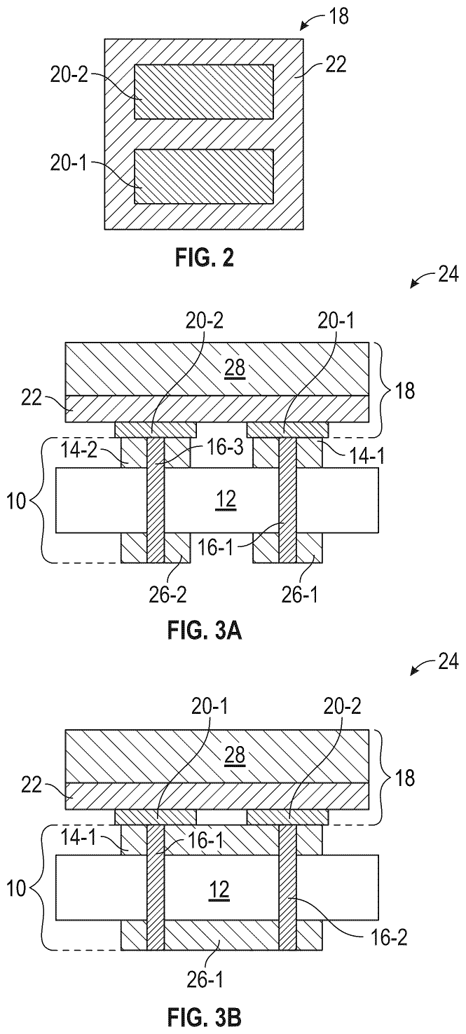

FIG. 2 is a bottom view of an LED chip 18 that may be mounted to the submount structure 10 of FIGS. 1A and 1B. In the example of FIG. 2, the LED chip 18 embodies a flip-chip structure where anode and cathode pads 20-1, 20-2 of the LED chip 18 are on a same side for flip-chip mounting. The anode and cathode pads 20-1, 20-2 are electrically coupled to an active LED structure 22 of the LED chip 18. For illustrative purposes, other elements of the LED chip 18, such as various passivation layers, reflective layers, and current spreading layers, are omitted.

FIG. 3A is a cross-sectional view of an exemplary LED package 24 that includes the LED chip 18 of FIG. 2 flip-chip mounted to the submount structure 10 of FIGS. 1A and 1B. The view of FIG. 3A is from the perspective of the cross-sectional line A-A as illustrated in FIG. 1B. As illustrated, the anode and cathode pads 20-1, 20-2 are electrically coupled and bonded to corresponding ones of the bonding pads 14-1, 14-2. The LED package 24 may further include package mounting pads 26-1, 26-2 on a backside of the submount 12 of the submount structure 10. The package mounting pads 26-1, 26-2 may be electrically coupled to the bonding pads 14-1, 14-2 by way of the vias 16 for embodiments where the vias 16-1, 16-3 include electrically conductive materials. For embodiments where the vias 16-1, 16-3 include insulating materials or air, the package mounting pads 26-1, 26-2 may be electrically coupled to the bonding pads 14-1, 14-2 by way of other electrically routing (e.g., electrical traces and/or other vias) through the submount 12. As described above, the vias 16-1, 16-3 may comprise materials selected to provide spatial CTE variations along the bonding surfaces between the anode and cathode pads 20-1, 20-2 and the bonding pads 14-1, 14-2. The corresponding CTE profile along the mounting surfaces may be tailored to reduce stress and instances where the LED chip 18 may delaminate from the submount structure 10. In certain embodiments, the vias 16-1, 16-3 may extend through an entire thickness of the submount 12 and through portions of the bonding pads 14-1, 14-2 and/or the package mounting pads 26-1, 26-2. In still further embodiments, the vias 16-1, 16-3 may extend entirely through the bonding pads 14-1, 14-2 and/or the package mounting pads 26-1, 26-2. By way of example, the LED chip 18 includes a substrate 28 on which the active LED structure 22 is grown. For flip-chip embodiments, the substrate 28 may form a primary light-emitting surface of the LED chip 18.

FIG. 3B is another cross-sectional view of the LED package 24 of FIG. 3A illustrating vias 16-1, 16-2 that extend through the same bonding pad 14-1. The view of FIG. 3B is from the perspective of the cross-sectional line B-B as illustrated in FIG. 1B. As described above, the via 16-1 may form a different CTE than the via 16-2, thereby varying the CTE across the bonding pad 14-1. In one example, the vias 16-1, 16-2 may each comprise a same host material, such as silicone, with different loadings of metal or ceramic particles. In another example, one of the vias 16-1 may be air filled while the other via 16-2 has one of the via materials listed above.

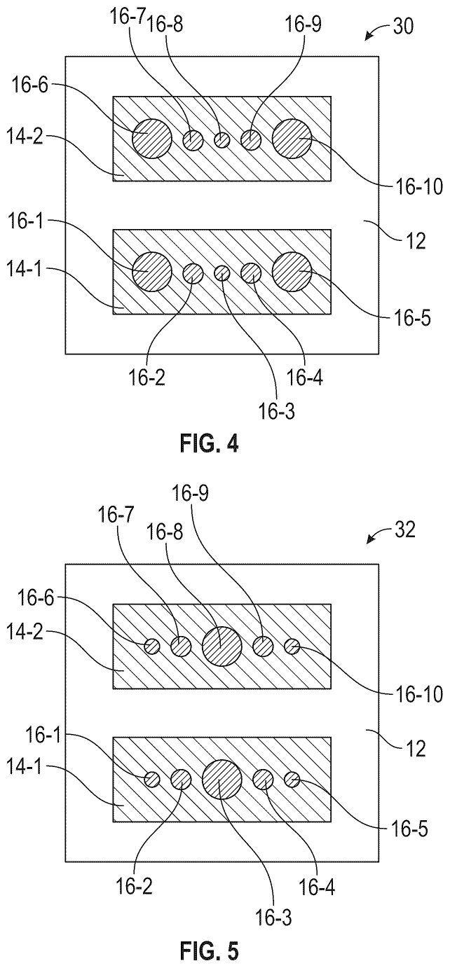

FIG. 4 is a top view of a submount structure 30 that is similar to the submount structure 10 of FIGS. 1A and 1B with a different arrangement of vias 16-1 to 16-10. For the submount structure 30, the vias 16-1 to 16-5 corresponding with the bonding pad 14-1 are formed with different diameters along the bonding pad 14-1 to provide variable CTE. For example, the vias 16-1, 16-5 proximate opposing ends of the bonding pad 14-1 have larger diameters than the other vias 16-2 to 16-4. In further embodiments, the diameters of the vias 16-1 to 16-5 may progressively decrease from largest (e.g., 16-1, 16-5) to smallest (e.g., 16-3) toward a center region of the bonding pad 14-1. As illustrated, the vias 16-6 to 16-10 may have a similar arrangement with respect to the other bonding pad 14-2. The vias 16-1 to 16-10 may all comprise a same material where the varying diameters provide varying CTEs. In other embodiments the vias 16-1 to 16-10 may vary materials and diameters to provide further varying CTEs. In certain applications, delamination of LED chips and corresponding anode and cathode pads may occur along opposing edges of the bonding pads 14-1, 14-2. By tailoring the CTE in this manner, stress balancing may be achieved to avoid delamination, particularly when the submount 12 is formed of a flexible material.

FIG. 5 is a top view of a submount structure 32 that is similar to the submount structure 30 of FIG. 4 for another arrangement of vias 16-1 to 16-10. In FIG. 5, the largest vias 16-3, 16-8 are centrally positioned with respect to corresponding bonding pads 14-1, 14-2. In further embodiments, the diameters of vias 16-1 to 16-10 may progressively decrease from the center to opposing edges of each bonding pad 14-1, 14-2. As indicated above, delamination may of LED chips may occur along the opposing edges of each bonding pad 14-1, 14-2 due to uneven CTE profiles. For certain LED chip mounting arrangements, related CTE stress may be higher along the center portions of each bonding pad 14-1, 14-2, and the diameter arrangement of FIG. 5 may provide suitable CTE balancing.

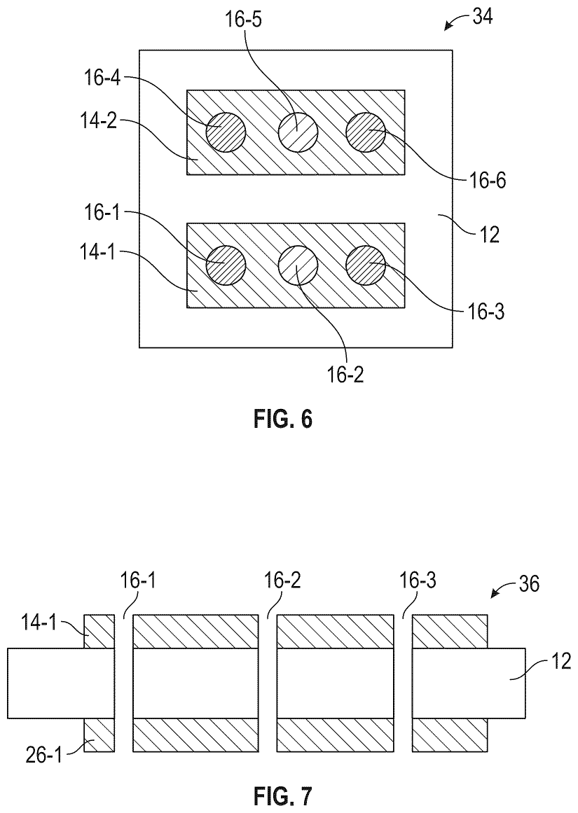

FIG. 6 is a top view of a submount structure 34 that is similar to the submount structure 30 of FIG. 4 for another arrangement of vias 16-1 to 16-6. In FIG. 6, the vias 16-1 to 16-6 may each have a same diameter and the varying CTE is provided by varying the material for the vias 16-1 to 16-6 with respect to each bonding pad 14-1, 14-2. For example, the centrally positioned vias 16-2, 16-5 may have different materials than the perimeter positioned vias 16-1, 16-3, 16-4, and 16-6 to compensate for center-to-edge CTE variations after LED chip bonding. The varying materials for the vias 16-1 to 16-6 may embody any of the materials listed above, including varying loading of metal or ceramic particles in a binder, continuous metals, air, graphene, and/or a graphene composite.

FIG. 7 is a cross-sectional view of a submount structure 36 similar to the submount structure 34 of FIG. 6 for embodiments where the vias 16-1 to 16-3 are air-filled vias. The cross-section of FIG. 7 is taken through the bonding pad 14-1 and intersecting the vias 16-1 to 16-3. In this manner, it is understood the bonding pad 14-1 forms a continuous metal structure around each of the vias 16-1 to 16-3 out of the plane of view. As illustrated, the vias 16-1 to 16-3 may form openings along the bonding pad 14-1 that provide CTE variations for stress balancing. In certain embodiments, the openings (e.g., air filled) are formed through an entire thickness of the submount 12 and through portions of the bonding pad 14-1 and the package mounting pad 26-1.

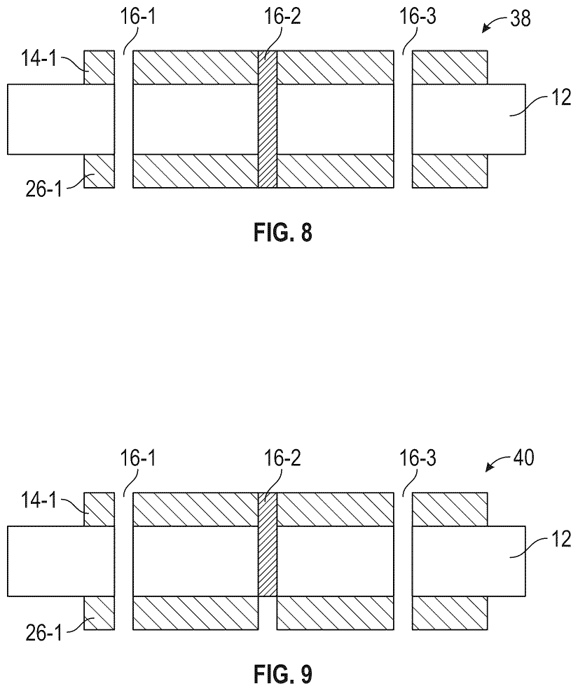

FIG. 8 is a cross-sectional view of a submount structure 38 similar to the submount structure 36 of FIG. 7 for embodiments where the vias 16-1 to 16-3 include air-filled vias and vias filled with other materials. By way of example, the perimeter vias 16-1, 16-3 may embody air-filled vias while the center via 16-2 may be filled with another material, such as any of the materials listed above, including varying loading of metal or ceramic particles in a binder, continuous metals, air, graphene, and/or a graphene composite. In other embodiments, the order may be reversed such that the center via 16-2 may embody an air-filled via while the perimeter vias 16-1, 16-3 may be filled with another material listed above.

FIG. 9 is a cross-sectional view of a submount structure 40 similar to the submount structure 38 of FIG. 8 for embodiments where one or more of the vias 16-1 to 16-3 are only partially filled. By way of example, the perimeter vias 16-1, 16-3 may embody air-filled vias while the center via 16-2 may be partially filled with another material, such as any of the materials listed above. As illustrated, the partial filling of the via 16-2 may extend through the bonding pad 14-1 and the submount 12, but not entirely through the package mounting pad 26-1. In other embodiments, the order may be reversed such that the center via 16-2 may embody an air-filled via while the perimeter vias 16-1, 16-3 may be partially filled with another material listed above.

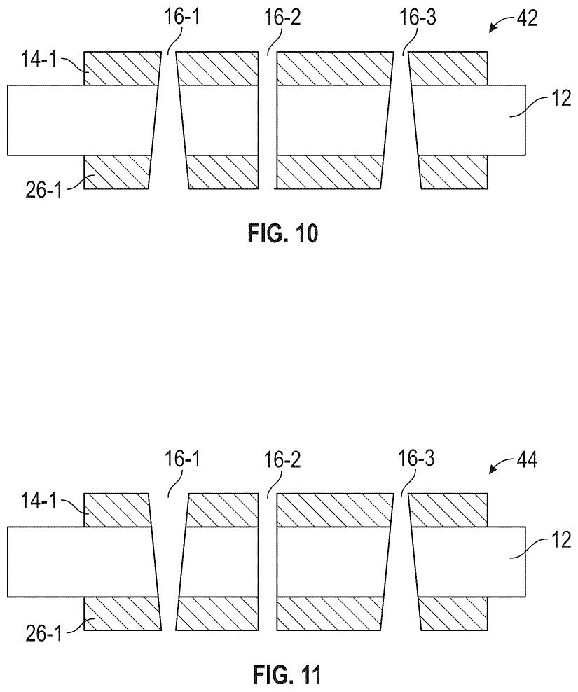

FIG. 10 is a cross-sectional view of a submount structure 42 similar to the submount structure 36 of FIG. 7 for embodiments where diameters of one or more of the vias 16-1 to 16-3 are variable through a thickness of the submount 12. Varying the diameter of one or more of the vias 16-1 to 16-3 may provide the ability to further tune CTE profiles in directions through the submount 12. By way of example, the perimeter vias 16-1, 16-3 are formed with diameters that progressively increase through the submount 12 in a direction from the bonding pad 14-1 towards the package mounting pad 26-1. Accordingly, CTE balancing within the submount 12 may be varied in lateral directions by adjusting a number of the vias 16-1 to 16-3 present, and in vertical directions through the submount 12 by varying diameters of one or more of the vias 16-1 to 16-3. In certain embodiments, the via 16-2 may be formed with a generally consistent diameter through the submount 12. As with other embodiments, the vias 16-1 to 16-3 may embody air-filled vias, vias filled with any of the materials described above, and combinations of air-filled and material-filled vias.

FIG. 11 is a cross-sectional view of a submount structure 44 similar to the submount structure 42 of FIG. 10 for embodiments where diameters of one or more of the vias 16-1 to 16-3 are variable in opposing directions. By way of example, the via 16-3 is formed with a diameter that progressively increases through the submount 12 in a direction from the bonding pad 14-1 towards the package mounting pad 26-1, and the via 16-1 is formed with a diameter that progressively decreases in the same direction. In this manner, CTE balancing within the submount 12 may be varied in lateral directions by adjusting a number of the vias 16-1 to 16-3 present, and in vertical directions through the submount 12 by varying diameters of one or more of the vias 16-1 to 16-3.

As described above, any of the previously described embodiments with respect to FIGS. 1A to 11 are applicable for CTE balancing in submounts and corresponding LED packages. The principles described are particularly well suited for CTE balancing in applications where the submounts embody flexible submounts.

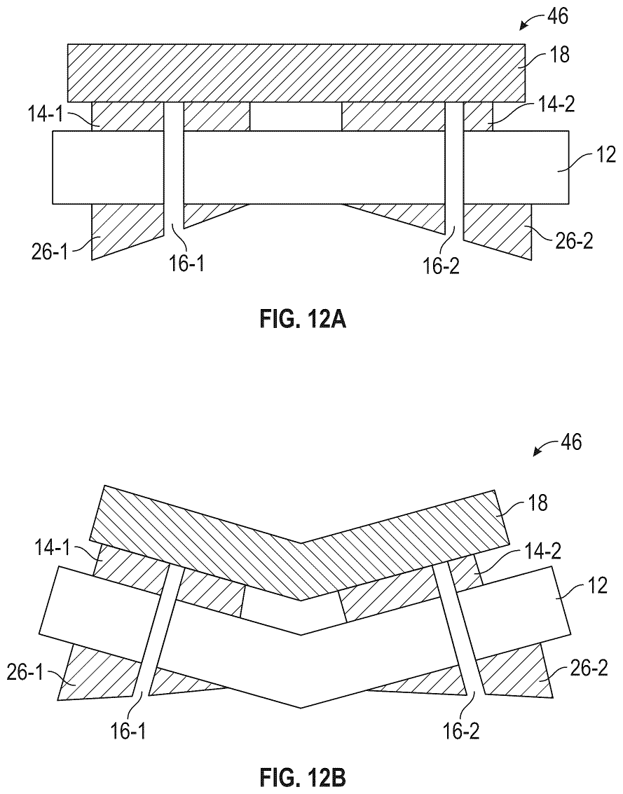

FIGS. 12A and 12B are cross-sectional views of an LED package 46 that is similar to the LED package 24 of FIGS. 3A and 3B for embodiments where the package mounting pads 26-1, 26-2 are formed with tapered thicknesses to accommodate flexibility in the submount 12. FIG. 12A is a cross-sectional view of the LED package 46 during bonding of the LED chip 18 to the submount 12 at elevated temperatures associated with bonding. By way of example, the submount 12 is formed with vias 16-1, 16-2, although the principles described are appliable to any number of vias with any number of fillers and/or shapes as described above with respect to FIGS. 1A to 11. As illustrated, the package mounting pad 26-1 is formed with a variable thickness on the bottom of the submount 12. For example, the thickness of the mounting pads 26-1, 26-2 may decrease in directions toward a center of the submount 12. FIG. 12B is a cross-sectional view of the LED package 46 after bonding of the LED chip 18 to the submount 12. In certain embodiments, the LED chip 18 may exhibit bowing after being bonded to the submount 12, particularly in embodiments where a growth substrate (e.g., 28 of FIGS. 3A and 3B) is removed after bonding with the submount 12. As illustrated, the bowing of the LED chip 18 may in turn cause flexing of the submount 12, particularly for embodiments where the submount 12 is formed of a flexible material. By forming the mounting pads 26-1, 26-2 with variable thickness as illustrated, the mounting pads 26-1, 26-2 may form more planar mounting surfaces along a bottom of the LED package 46, thereby increasing bonding integrity with other surfaces.

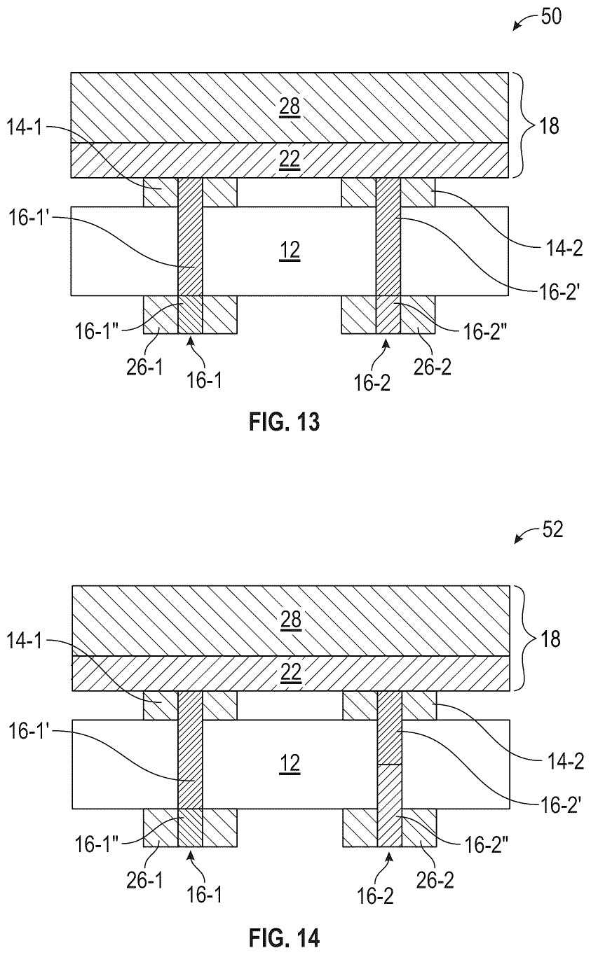

FIG. 13 is a cross-sectional view of an LED package 50 that is similar to the LED package 24 of FIGS. 3A and 3B for embodiments where one or more of the vias 16-1, 16-2 have portions filled with different materials. By way of example, the via 16-1 includes a first portion 16-1′ extending through the bonding pad 14-1 and the submount 12 and a second portion 16-1″ extending through the package mounting pad 26-1. The via 16-2 includes a first portion 16-2′ extending through the bonding pad 14-2 and the submount 12 and a second portion 16-2″ extending through the package mounting pad 26-2. The first portions 16-1′, 16-2′ and the second portions 16-1″, 16-2″ may include different filler materials, such as different ones and/or compositions of air, metal particles in a binder, ceramic powders in a binder, continuous metal fillers, graphene or graphene composites. As described above, different material compositions may also include the same materials but with different loading. Varying materials and/or compositions of filler materials for the vias 16-1, 16-2 may provide further CTE balancing through a thickness of the submount 12.

FIG. 14 is a cross-sectional view of an LED package 52 that is similar to the LED package 50 of FIG. 13 for a different arrangement of the vias 16-1, 16-2. In FIG. 14, the differing portions 16-2′, 16-2″ of the via 16-2 extend with different depths as compared with the differing portions 16-1′, 16-1″ of the via 16-1. For example, the first portion 16-2′ extends partially through the submount 12 from the bonding pad 14-2 while the second portion 16-2″ also extends partially through the submount 12 from the package mounting pad 26-2.

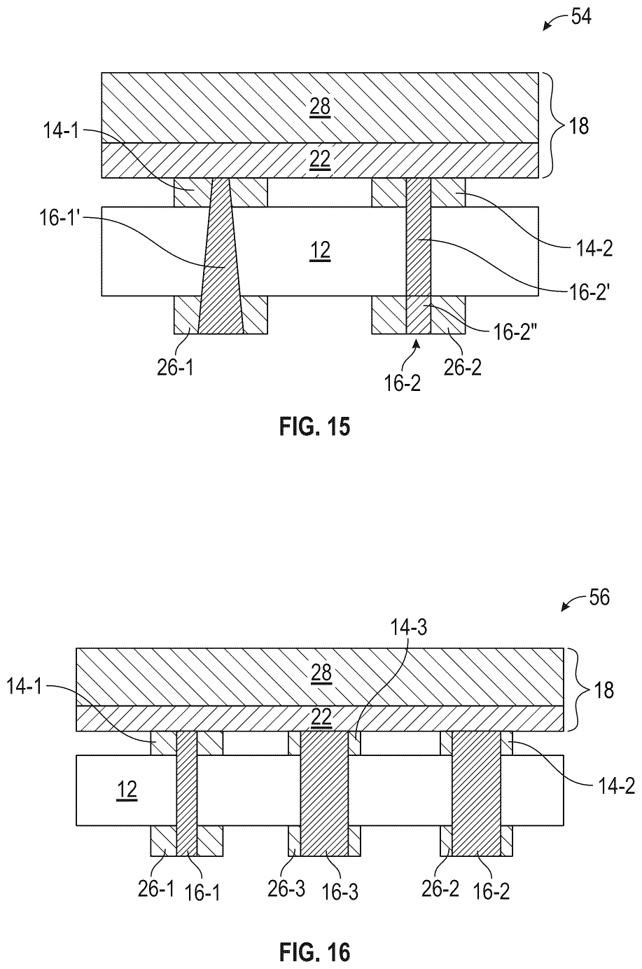

FIG. 15 is a cross-sectional view of an LED package 54 that is similar to the LED package 50 of FIG. 13 for embodiments where one via 16-1 is formed with a variable thickness while another via 16-2 is formed with variable filler materials. In this regard, the via 16-1 may be formed as described above with respect to FIG. 10 and the via 16-2 may be formed as described above with respect to FIG. 13 to provide specific CTE balancing profiles.

FIG. 16 is a cross-sectional view of an LED package 56 that is similar to the LED package 24 of FIGS. 3A and 3B for embodiments that include thermal dissipation structures. In certain embodiments, particularly for higher power and/or larger area LED chips 18, the LED package 56 may be formed with one or more heat dissipation pathways through the submount 12. It is appreciated that the vias 16-1, 16-2 may include thermally conductive materials suitable for dissipating heat, such as the continuous metal structures, graphene, and/or graphene composites as described above. In further embodiments, the LED package 56 may include a bonding pad 14-3, a corresponding package mounting pad 26-3, and a filled via 16-3 that form a thermal dissipation structure. The via 16-3 may be filled with the continuous metal structures, graphene, and/or graphene composites as described above. In certain embodiments, the thermal dissipation structure may be electrically isolated from the LED chip 18 while still effectively forming a heat sink. As illustrated, a diameter of the via 16-3 may be larger than a diameter of the via 16-1 for increased thermal dissipation. As further illustrated, the via 16-2 may be formed with increased thickness for increased thermal dissipation alone or in combination with embodiments that include the thermal dissipation structure formed by the bonding pad 14-3, the mounting pad 26-3, and the filled via 16-3.

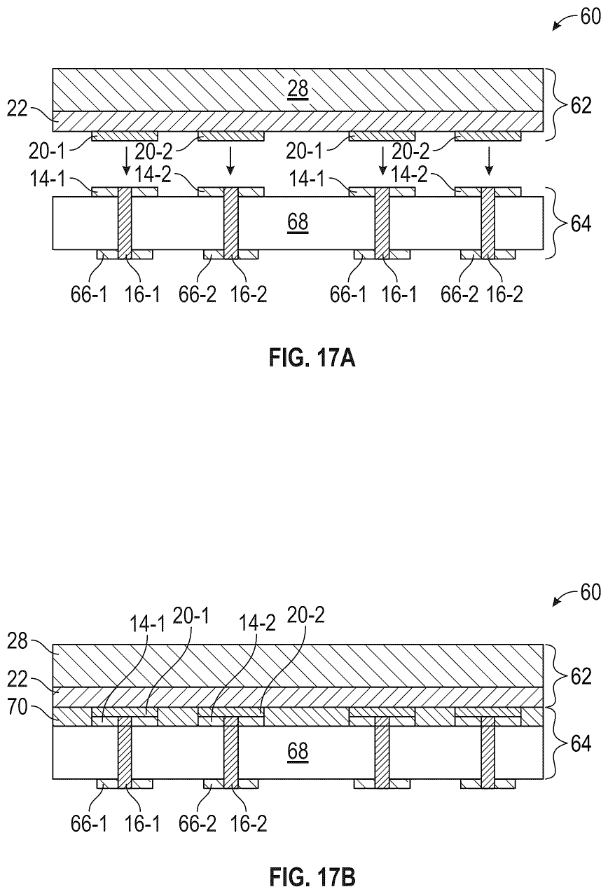

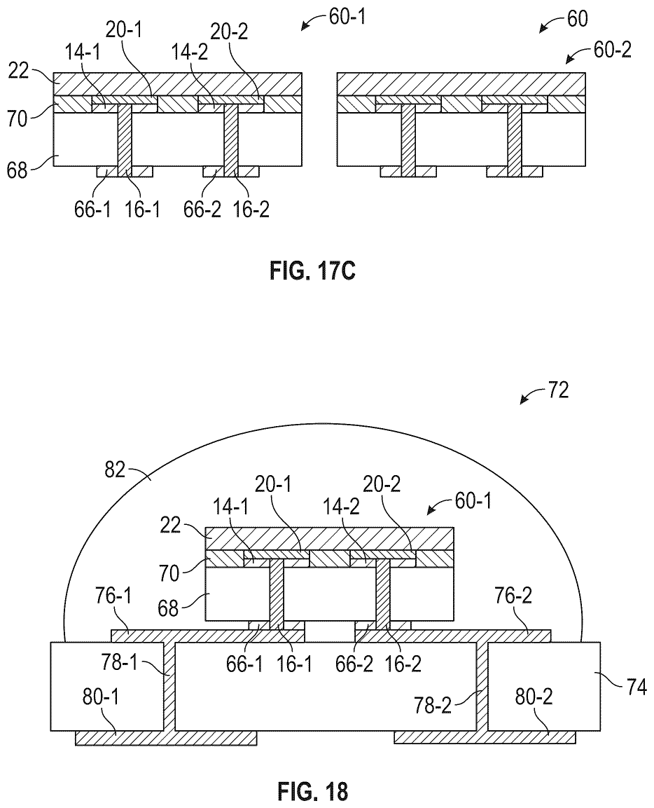

The principles described above for CTE balancing between LED chips and corresponding submounts are also applicable for chip-scale packaging. FIGS. 17A to 17C are cross-sectional views of a fabrication sequence for forming LED chips 60-1, 60-2 from an LED wafer structure 60 according to principles of the present disclosure.

FIG. 17A is a cross-sectional view of the LED wafer structure 60 at a fabrication step before an LED wafer 62 is bonded to a submount structure wafer 64. For the LED wafer 62, the active LED structure 22 and the substrate 28 are continuous for multiple LED chip regions. For illustrative purposes, only two LED chip regions are illustrated. In practice, the LED wafer 62 may include many more LED chip regions that are fabricated together. Since the LED wafer structure 60 is described for chip-level packaging, the package mounting pads 26-1, 26-2 and the submount 12 of previous embodiments are respectively referred to as chip mounting pads 66-1, 66-2 and a chip submount 68. FIG. 17B is a cross-sectional view of the LED wafer structure 60 at a fabrication step after the LED wafer 62 is bonded to the submount structure wafer 64 by way of a bonding material 70. FIG. 17C is a cross-sectional view of the LED wafer structure 60 at a fabrication step after the LED wafer structure 60 is subdivided into individual LED chips 60-1, 60-2. In certain embodiments, the substrate 28 of FIGS. 17A and 17B may be removed before the individual LED chips 60-1, 60-2 are separated. Accordingly, each LED chip 60-1, 60-2 may include the active LED structure 22 bonded to the submount 12 with vias 16-1, 16-2 structured to provide CTE balancing. The vias 16-1, 16-2 may embody any of the examples provided above with respect to FIGS. 1A to 16. As described above, the principles of CTE balancing are particularly useful for applications where the submount 12 embodies a flexible submount.

FIG. 18 is a cross-sectional view of an LED package 72 that includes the LED chip 60-1 of FIG. 17C. The LED package 72 may include a package submount 74 with package bond pads 76-1, 76-2 arranged to receive the chip mounting pads 66-1, 66-2. Package submount vias 78-1, 78-2 may extend through the package submount 74 to electrically connect with package mounting pads 80-1, 80-2. An encapsulant 82 may cover the LED chip 60-1 on the package submount 74 and, in certain embodiments, the encapsulant 82 may form the shape of a lens for directing light emissions from the LED chip 60-1. In certain embodiments, the chip submount 68 for the LED chip 60-1 is flexible in nature and the vias 16-1, 16-2 provide CTE balancing. Accordingly, the LED chip 60-1 may be well suited for mounting within the LED package 72 and accommodating any irregularities or nonplanar mounting surfaces.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a submount;
a first bonding pad on the submount;
an LED chip mounted to the first bonding pad; and
a first via and a second via extending through the submount and at least a portion of the first bonding pad, the first via having a first coefficient of thermal expansion that is different than a second coefficient of thermal expansion of the second via.

2. The LED package of claim 1, further comprising a second bonding pad on the submount, wherein an anode pad of the LED chip is bonded to the first bonding pad and a cathode of the LED chip is bonded to the second bonding pad.

3. The LED package of claim 2, further comprising a third via and a fourth via extending through the submount and at least a portion of the second bonding pad, the third via having a third coefficient of thermal expansion that is different than a fourth coefficient of thermal expansion of the fourth via.

4. The LED package of claim 1, further comprising a first package mounting pad on a side of the submount opposite the first bonding pad, wherein the first via and the second via extend through at least a portion of the first package mounting pad.

5. The LED package of claim 1, wherein the submount comprises a flexible submount.

6. The LED package of claim 5, wherein the flexible submount comprises polyimide or polyethylene terephthalate.

7. The LED package of claim 1, wherein the first via comprises a different material than the second via.

8. The LED package of claim 7, wherein the first via comprises an air-filled via and the second via is at least partially filled with another material that is different from the air-filled via.

9. The LED package of claim 8, wherein the second via is entirely filled with the material that is different from the air-filled via.

10. The LED package of claim 1, wherein the first via and the second via comprise particles filled within a binder, and a loading concentration of the particles in the binder of the first via is different than the second via.

11. The LED package of claim 1, wherein the first via comprises a larger diameter than the second via.

12. The LED package of claim 11, wherein the second via is positioned proximate a center region of the first bonding pad, and the first via is positioned proximate an end of the first bonding pad.

13. The LED package of claim 11, wherein the first via is positioned proximate a center region of the first bonding pad, and the second via is positioned proximate an end of the first bonding pad.

14. The LED package of claim 1, wherein a diameter of the first via progressively increases or decreases through the submount.

15. The LED package of claim 14, wherein a diameter of the second via is consistent through a thickness of the submount.

16. The LED package of claim 1, wherein a first portion of the first via is filled with a different material than a second portion of the first via.

17. A light-emitting diode (LED) package comprising:
a submount;
a first bonding pad and a second bonding pad on a first side of the submount;
an LED chip bonded to the first bonding pad and the second bonding pad; and
a first mounting pad and a second mounting pad on a second side of the submount opposite the first side, the first mounting pad and the second mounting pad comprising tapered thicknesses on the second side of the submount.

18. The LED package of claim 17, wherein the tapered thicknesses of the first mounting pad and the second mounting pad decrease in directions toward a center of the second side of the submount.

19. The LED package of claim 17, wherein the submount is configured to flex so that the first mounting pad and the second mounting pad form planar mounting surfaces on the second side of the submount.

20. The LED package of claim 17, further comprising at least one via extending through the submount and at least a portion of the first bonding pad.

21. A light-emitting diode (LED) package comprising:
a submount;
a first bonding pad, a second bonding pad, and a third bonding pad on a first side of the submount; and
an LED chip bonded to the first bonding pad, the second bonding pad, and the third bonding pad, the LED chip being electrically connected to the first bonding pad and the second bonding pad, and the LED chip being electrically isolated from the third bonding pad.

22. The LED package of claim 21, further comprising a first via extending through the submount and at least a portion of the first bonding pad, a second via extending through the submount and at least a portion of the second bonding pad, and a third via extending through the submount and at least a portion of the third bonding pad.

23. The LED package of claim 22, wherein the third via comprises a larger diameter than the first via.

24. A light-emitting diode (LED) chip comprising:
a chip submount;
a first bonding pad on the chip submount;
an active LED structure bonded to the first bonding pad; and
a first via and a second via extending through the chip submount and at least a portion of the first bonding pad, the first via having a first coefficient of thermal expansion that is different than a second coefficient of thermal expansion of the second via.

25. The LED chip of claim 24, further comprising a second bonding pad on the chip submount, wherein an anode pad of the active LED structure is bonded to the first bonding pad and a cathode of the active LED structure is bonded to the second bonding pad.

26. The LED chip of claim 25, further comprising a third via and a fourth via extending through the submount and at least a portion of the second bonding pad, the third via having a third coefficient of thermal expansion that is different than a fourth coefficient of thermal expansion of the fourth via.

27. The LED chip of claim 24, further comprising a first chip mounting pad on a side of the submount opposite the first bonding pad, wherein the first via and the second via extend through at least a portion of the first chip mounting pad.

28. The LED chip of claim 24, wherein the chip submount comprises a flexible submount.
